(19) United States
(12) Patent Application Publication
(10) Pub. No.: US 2003/0054105 A1
(43) Pub. Date: Mar. 20, 2003

(54) Film growth at low pressure mediated by liquid flux and induced by activated oxygen

(76) Inventors: Robert H. Hammond, Los Altos, CA (US); Luke S. J. Peng, Mountain View, CA (US); Weizhi Wang, San Jose, CA (US); William Jo, Mountain View, CA (US); Tsuyoshi Ohnishi, Ichikawa (JP); Malcolm R. Beasley, Palo Alto, CA (US)

Correspondence Address: LUMEN INTELLECTUAL PROPERTY SERVICES, 45 CABOT AVENUE, SUITE 110, SANTA CLARA, CA, 95051, US

(21) Appl. No.: 10/220,000

(22) Filed: Aug. 14, 2002

Related U.S. Application Data
(60) Provisional application No. 60/312,377, filed on Aug. 14, 2001.

(51) Int. Cl. C23C 16/00; B05D 1/18; B05D 3/00

(52) U.S. Cl. 427/294; 427/443.2; 427/248.1; 118/723 ME; 118/723 EB; 118/724; 118/666

(57) ABSTRACT

The present invention is useful in growing complex films with high quality (low lattice strain, large grain size, high degree of perfection) at high rates and large area, and high efficiency use of material. A solid-state film is grown from a liquid, where atoms are supplied continuously by vapor deposition onto the liquid surface. The desired film material grows from or is precipitated from the liquid flux, which is in thermodynamic equilibrium with the desired film. The desired film growth starts at a substrate interface. If this is a biaxial textured surface suitable in chemical reactivity and lattice constant, the growth will be epitaxial with the substrate. The atomic mixture that forms the deposited film is supplied by the arrival of the atoms from a vapor onto the surface of the liquid flux. An important additional factor in the case of an oxide such as the HTSC YBCO is that activated oxygen needs to be present, along with molecular oxygen. This is key to allowing the inventive process to occur at low oxygen pressure.

### CROSS-REFERENCE TO RELATED APPLICATIONS

This application claims the benefit of U.S. Provisional Application No. 60/312,377, filed Aug. 14, 2001, which is hereby incorporated herein by reference.

### STATEMENT REGARDING FEDERALLY SPONSORED RESEARCH OR DEVELOPMENT

This invention was supported in part by the U.S. Department of Energy (DOE) under contract number 19XTA478C. SPO No. 20165. The U.S. government has certain rights in this invention.

### BACKGROUND OF THE INVENTION

1. Field of the Invention

The present invention relates generally to methods for growing films at low pressures and mediating the growth by liquid flux, and more particularly to promoting the film growth at the low pressure by controlling the content of activated oxygen in the atmosphere.

2. Description of the Related Art

Yttrium-barium-copper-oxide (YBCO) is a complex metal oxide with a kind of layering called a Perovskite structure. Scientists are interested in YBCO because when it is cooled below around 90 Kelvin, which can be accomplished with low cost liquid nitrogen, it becomes a superconductor. Specifically, YBCO experiences a phase change on the quantum mechanical level at approximately 90 Kelvin. At this temperature, the electrons begin to form pairs due to a weak attraction—a result of the electrons' interaction with the crystal lattice of the YBCO atoms. The paired electrons share the same quantum mechanical wave function. As such, if one electron runs into an impurity in the YBCO it will only stop if all of the paired electrons come to a stop. Since a single impurity is incapable of stopping all of the electrons, the electron in question will pass the impurity without being scattered. As a consequence, the YBCO becomes a perfect conductor with absolutely zero resistance. The two most important properties of YBCO are that it has no electrical resistance and that it expels a magnetic field.

To date, growing or otherwise producing high quality high temperature (high T_{c}) superconductors (HTSC) is still technically very difficult and economically cost prohibitive. This is because grown films exhibit a limitation in critical current density (J_{c}) due to random or non-preferred crystal orientation and grain boundary effects and atmospheric poisoning effects. For scale-up large area applications, for example, fabricating superconducting cables for transporting electrical power, the requirements are even more challenging: c-axis epitaxial with the in-plane alignment grain to grain better than approximately 2 degrees (4 degrees may be sufficient), onto a strong metallic tape kilometers long, and with critical current densities as good as found under ideal conditions on single crystal oxide substrates. What is more, the economical constraints require deposition rates to be greater than 10 nm/sec and thickness of microns or more, over large areas. These requirements means that the overall system pressure must be low to provide large mean free path, hence high rates, and permit the use of in-situ process control using electrons to probe the surfaces. As discussed herein, the use of molecular oxygen at the values needed for thermodynamic stability (10-30 mTorr) at reasonable growth temperatures, however, is not advisable.

There are now two leading technologies for producing the biaxial textured substrates for coated conductors, the so-called second-generation superconductors, namely ion beam assisted deposition (IBAD) and rolling assisted biaxially textured substrates, (RABiTS) processes. In the IBAD process, a biaxially textured layer of metal oxide, typically Yttrium-Stabilized-Zirconium (YSZ) or, more recently, MgO (e.g., U.S. Pat. No. 6,190,752, assigned to the assignee of the present invention on Feb. 20, 2001), is deposited on a flexible metallic substrate with the assistance of an ion gun, which is positioned at an angle to the metallic substrate. The YSZ (or MgO) plume is produced by evaporation or by sputtering. Typical IBAD deposition rates are about 1.5 Å/sec. At this rate, it takes nearly two hours to obtain a 1 micron thick layer of YSZ. On the other hand, IBAD-MgO only requires about 100 Å thickness and thus is 100 times faster. An exemplary teaching on IBAD process can be found in “Thick Film YBCO for Wires and Tapes: Scale-up Issues and Cost Estimates”, by co-inventor R. H. Hammond, Advances in Superconductivity VIII. Proc. 8th Int. Symp. Supercond. (ISS) (Springer Verlag, Tokyo, 1996) p. 1029, which is hereby incorporated herein by reference. Considerations on the scale up of the YBCO process at issue here is also presented.

Currently, superconducting films are grown from the vapor state to the solid state via vapor deposition or the like. The resulting morphology is determined by the surface mobility. To understand the growth behavior of the superconducting films such as YBCO films, it is useful to look into single crystal growth using liquid phase epitaxy (LPE) of YBCO in a liquid flux of BaₓCu_{y}O_{z}. Recently, Kawasaki et al. reported, in Proceedings of the 3rd Symposium on Atomic Scale Surface and Interface Dynamics, 3 (1999) 151, a method to grow single crystalline thin YBCO films at high pressure (200 mTorr of O₂) using pulsed laser deposition (LPD) at low rate (˜1 Å/sec) onto a liquid flux of BaCu₂O₂. It has also been shown in “Homoepitaxial Growth of YBA₂Cu₃Oₓ Films” by T. Morishita et al., Chinese J. of Physics, V. 36, No. 2-11, April, 1998, that YBa₂Cu₃Oₓ films can be grown on single crystal YBCO substrates by metalorganic chemical vapor deposition (MOCVD). However, as reported by T. Morishita et al., the surface of YBCO substrate deteriorates above 400° C. in oxygen pressures below 5×10⁻⁵ Torr. Specifically, outside the oxygen pressure range from one mTorr to one Torr, the YBCO is thermodynamically unstable and decomposes. FIGS. 1 and 2 detail the stability as a function of temperature and oxygen activity.

For the foregoing reasons, there is a need for a new method for in-situ high rate growth of a high quality high temperature superconducting film from a liquid at reduced pressure.

### SUMMARY OF THE INVENTION

The present invention addresses this need by providing new techniques in growing superconducting films and especially in growing high quality high temperature superconducting thin films containing oxides on substrates in oxygen pressure below 5×10⁻⁵ Torr. The growing techniques of the present invention enable films be grown with low lattice strain, large grain size and a high degree of perfection at high growth rates and covering large areas. The growing techniques of the present invention further ensure highly efficient use of material. The inventive growing techniques of the present invention relate to liquid phase epitaxy (LPE) with several novel and unobvious distinctions directed to the thermodynamic stability and kinetics of YBCO film growth at high rates in atomic and molecular oxygen.

There are several important differences from the LPE technique and the above-mentioned Kawasaki et al. report:

1. Both methods are at high oxygen pressure, in thermodynamic equilibrium with molecular oxygen supplied. The present process is in a low background oxygen pressure (<10⁻⁴ Torr) but a high oxygen activity is obtained. This activated oxygen is either from supplied activated oxygen (atomic oxygen and ozone have been used—there are other sources of activated oxygen, such as N₂O, etc.), or is generated in the process at the electron beam sources.

2. Both LPE and the Kawasaki et al. methods result in a perfect YBCO (or rare-earth BCO) crystal, which is called “layer-by-layer” growth. This perfect crystal is not useful for superconducting applications for two reasons: the perfect crystal does not allow additional oxygen to diffuse onto the material, to the “chains”. This additional oxygen is added during cool-down after formation and is required to make it a superconductor. Secondly, in order for the superconductor to carry a high super current there must be so-called “pinning sites”. Imperfections in the crystal are believed to help in the pinning. The desired morphology is a “faulted” structure, referred to as “island” growth morphology.

In the process described herein, a mixture of the perfect (layer-by-layer) and the island growth are formed as shown in FIG. 4. The island region has the high current. None flows in the perfect region, as we have proved in etching experiments. We found as the rate of the deposition is increased, e.g., from 20, to 50, then to 100 Å/sec, the fraction of island growth increases, resulting in a higher average critical current carrying capacity. At 100 Å/sec we find approximately 50% island, with an average critical current of greater than 2×10⁶ Amp/cm² at 77° K. (liquid nitrogen), zero magnetic field. The increase in the island fraction is consistent with the idea that the high rate results in greater supersaturation in the liquid BaCuO, which results in a high nucleation rate, and thus island growth. It is expected that still higher rates will make a still larger fraction of island growth, and thus a high critical current. A high critical current and a high rate both are directly related to the cost/performance ratio. This is discussed in the previously referenced article (Hammond, Advances in Superconductivity, VIII, ISS '96).

According to an aspect of the invention, a solid-state film is grown from a liquid, where atoms are supplied continuously by vapor deposition onto the liquid surface. The desired film material grows from or is precipitated from the liquid flux, which is in thermodynamic equilibrium with the desired film. The desired film growth starts at a substrate interface. If this is a biaxial textured surface suitable in chemical reactivity and lattice constant, the growth will be epitaxial with the substrate. The atomic mixture that forms the deposited film is supplied by the arrival of the atoms from a vapor onto the surface of the liquid flux. An important additional factor in the case of an oxide such as the HTSC YBCO is that activated oxygen needs to be present, along with molecular oxygen. This is key to allowing the inventive process to occur at low oxygen pressure.

Specifically, according to an aspect of the invention, high temperature superconductor YBa₂Cu₃O₇₋ₓ thin films are grown using in-situ electron beam evaporation at deposition rates over 1-10 nm/sec. The higher activity of atomic oxygen is being explored along with molecular oxygen at reduced pressure below 5×10⁻⁵ Torr. The YBa₂Cu₃O₇₋ₓ is observed to be stable within a band of atomic oxygen flux and temperature, similar to known YBCO in molecular oxygen but many orders of magnitude lower in oxygen pressure. The phase equilibrium is determined to be different from that found for molecular oxygen at low rates, as discussed herein with reference to FIG. 5.

Still further objects and advantages of the present invention will become apparent to one of ordinary skill in the art upon reading and understanding the following drawings and detailed description discussed herein. As it will be appreciated by one of ordinary skill in the art, the present invention can be implemented or otherwise altered in many ways without departing from the spirit and scope of the invention. Accordingly, the drawings are for illustrating purposes only and are not to be construed as limiting the present invention.

### BRIEF DESCRIPTION OF THE FIGURES

FIG. 1 illustrates oxygen flux vs. 1/T and thermodynamic phase stability limits. The corresponding oxygen pressure is shown on the right axis. Solid lines d₁(O₂), d₂(O₂), and m₁(O₂) are decomposition and melting lines of YBCO for molecular oxygen. The YBCO phase is stable between lines d₁ and d₂ where some well known processes are indicated.

FIG. 2 illustrates the YBCO phase stability in accordance with an embodiment of the present invention showing the results of our determination of the oxygen activity based on the fit of our results to the boundaries of stability and to the melting line of the BaCuO. High critical current are found for samples away from all boundaries, within lines B, D, C, and E.

FIG. 3 is an exemplary system setup for implementing the present invention.

FIG. 4 is a TEM micrograph with a corresponding schematic showing the “island” faulted growth, and the perfect “layer-by-layer” growth. Y₂O₃ and CuO as well as YBCO can be seen.

FIG. 5 illustrates phase relationship as expected for the pressure-temperature region based on bulk samples, and the proposed metastable diagram based on finding Y₂O₃ co-existing with YBCO and BaCuO liquid.

FIG. 6 shows selected x-ray diffractograms of in-situ grown YBCO films: (a) 13 Å/sec at 820° C. with atomic oxygen, (b) 50 Å/sec at 880° C. with molecular oxygen, (c) and (d) 100 Å/sec at 895° C. with molecular oxygen. (a), (b), and (c) are on STO substrates, while (d) is on an IBAD YSZ/Ni tape.

FIG. 7 is an x-ray φ-scan of an in-situ grown YBCO film on an IBAD YSZ/Ni tape in accordance with an aspect of the invention.

### DETAILED DESCRIPTION

As discussed heretofore, for scale-up large area applications, the requirements are challenging: c-axis epitaxial with the in-plane alignment grain to grain better than approximately 2 degrees, onto a strong metallic tape kilometers long, and with critical current densities as good as found under ideal conditions on single crystal oxide substrates. In addition, the economical constraints require the growth rate to be higher than 100 Å/sec over large area with thickness of more than one micron and critical current density J_{c} greater than 1 MA/cm². This means that the overall system pressure must be low to provide large mean free path, hence high rates, and allow the use of in-situ process control with electrons to probe the surfaces. The in-situ e-beam deposition process is believed to be an appropriate technique. However, the molecular oxygen partial pressure required for thermodynamic stability is too high for e-beam sources and the mean free path is too restrictive for scale-up to large areas. To date, as reported by various scientific journals and literature including T. Morishita et al., it is not advisable to use molecular oxygen at the values needed for thermodynamic stability (10-30 mTorr) at reasonable growth temperatures. The present invention explores the higher activity of atomic oxygen and ozone as well as molecular oxygen at reduced pressure (5×10⁻⁵ Torr or less). We have found that YBCO is stable within a band of atomic oxygen flux and molecular oxygen pressure, about 10⁻⁴ Torr (0.1 mil Torr), which is about a factor of 2000 less than what is required by Kawasaki et al. and many orders of magnitude less than YBCO in molecular oxygen published by Lindemer et al., in “Decomposition of YBa₂CuO₇₋ₓ and YBa₂Cu₄O₈ for po₂=0.1 MPa”, Physica C178 (1991) 93, and by Feenstra et al., “Effect of Oxygen Pressure on the Synthesis of YBa₂CuO₇₋ₓ Thin Films by Post-Deposition Annealing”, J. Appl. Phys. 69 (1991) 6569. According to the present invention, the presence of a small amount of activated oxygen allows for the lower pressure.

The advantages of low pressure film growth are numerous. In low pressure, there is less scattering, which results in a longer path for the atoms from the source to the growth substrate, thus a higher rate. The decreased scattering also leads to large area deposition and a greater efficiency of the use of the material. More importantly, the low pressure allows for in-situ electron beam evaporation be utilized to grow solid state films from a liquid. Growth from a liquid flux provides a large increase in the surface mobility, which results in a more perfect crystal growth. Because of the high mobility in the liquid flux, growth from a liquid flux has an additional advantage that the arrival rate of the atoms, in the case of a multi-element material, need only be in the desired ratio on average. Instantaneous fluctuations may not be important.

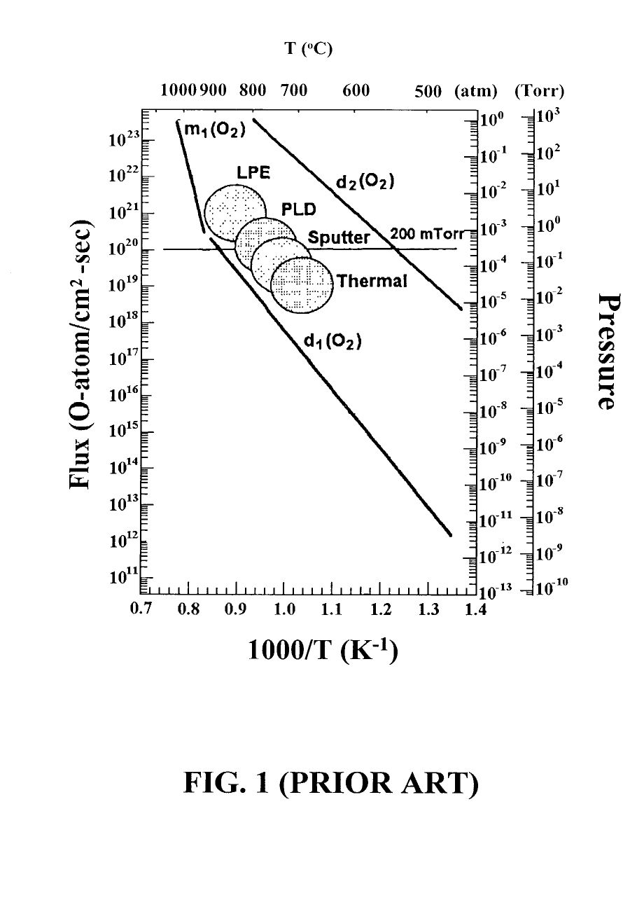

FIG. 1 shows the part of the partial pressure of oxygen-temperature phase space where YBCO is thermodynamically stable below atmospheric pressure of oxygen, as presently understood from thermodynamic studies by Lindemer et al. The main features of the molecular oxygen thermodynamic data are the melting-decomposition line, m₁(O₂), relevant at higher oxygen pressures, and a solid-state decomposition line at lower pressures, d₁(O₂), and another decomposition line at a high pressure-lower temperature, d₂(O₂). The YBCO phase is stable to the right side of m₁(O₂) and d₁(O₂) and to the left side of d₂(O₂). The thermodynamic studies of Lindemer et al. were performed on bulk samples. It is not a priori obvious whether such studies are important for thin film growth where one can in principle form metastable phases. The relevance of the stability line for in-situ growth of cuprites was first reported by co-inventor R. H. Hammond in Physica C162-164 (1989) 703, which is incorporated herein by reference. For further studies on thermodynamic line, molecular oxygen pressure, and mean free path, readers are referred to Schlom et al., MBE Growth of High T_{c} Superconductors, Molecular Beam Epitaxy: Applications to Key Materials, Ed. R. F. C. Farrow (Noyes, Park Ridge, 1995), Ch. 6, pp. 505-622.

Because of the relatively high deposition temperatures compared to the melting temperature (0.8-0.9 Tₘ) kinetics may not be limiting. The regions corresponding to successful thin film synthesis with molecular oxygen lie in the part of the diagram where YBCO is thermodynamically stable, as judged by extrapolating the thermodynamic lines to lower pressures and temperatures. This is in agreement with the expectation that one should be able to crystallize YBCO only where it is the lowest energy state.

In order to circumvent the pressure-temperature limitations of molecular oxygen, researchers have utilized activated species of oxygen, such as atomic oxygen or ozone. An exemplary teaching can be found in Missert et al., IEEE Trans. Magn. 25 (1989) 2418, which is incorporated herein by reference. These activated species of oxygen have an activity higher than molecular oxygen and therefore will more readily oxidize the metal atoms. Naturally, these activated species cannot be in thermodynamic equilibrium, otherwise O₂ would form. Thus, it is not clear how relevant a thermodynamic comparison is. It is difficult to establish where the corresponding stability is located for atomic oxygen, because it is hard to measure the flux (or pressure) accurately. Attempts have been made to quantify the corresponding line between CuO and Cu₂O for atomic oxygen and ozone, e.g., Schlom et al., supra, at 546-548.

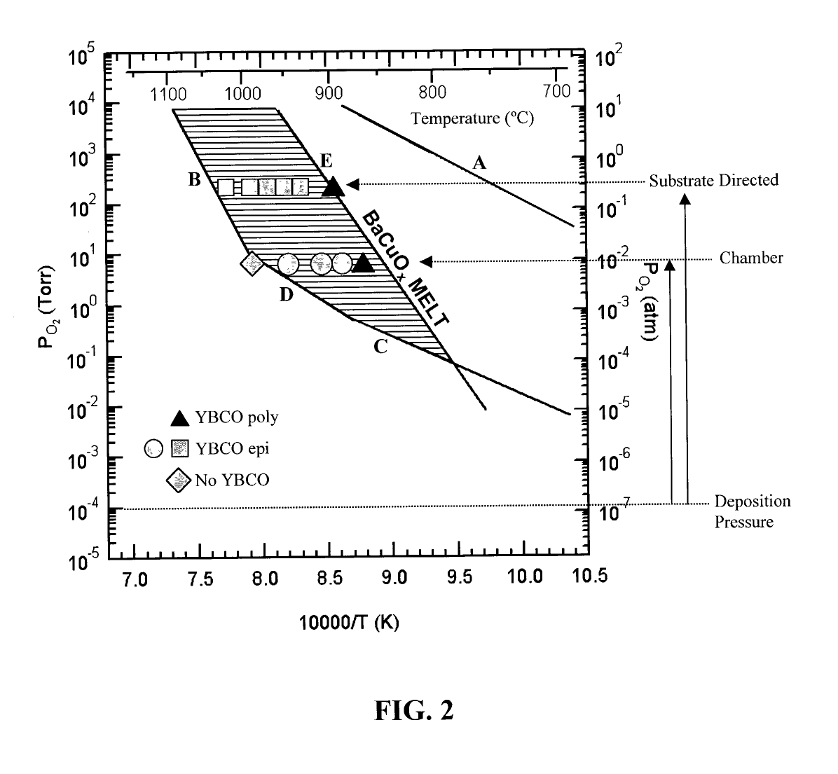

In FIG. 2, the region where we find high current samples are shown to be in the boundary where YBCO is stable, as well as above the melting line of BaCuO. To the right of this curve the deposit is polycrystalline with very low critical current. This demonstrates that high temperature deposition alone is not sufficient at the high rates—surface mobility due to temperature is not adequate at high rate, even though at low rates (˜1 Å/sec) it is.

Deposition is made with three elemental sources: Y(99.9% purity), Ba(99.5%), and Cu(99.9%). A Ta or W crucible is used for the Y source, a Mo crucible for Ba, and a graphite crucible for Cu. The primary pressure limitation in the chamber comes from the maximum pressure at which the electron beam guns can be operated. This maximum pressure is ˜10⁻⁴ Torr. In this example, growth rates of 13-100 Å/sec have been carried out under 5×10⁻⁵ Torr molecular oxygen. The Y, Ba, and Cu flux ratio was subject to near stoichiometry with a slight Ba deficiency. Substrate temperature was maintained at 800 to 900° C. during deposition. After deposition, the samples were cooled down to room temperature in molecular oxygen at increasing pressure. This supplies oxygen to the chain, and make it a superconductor.

E-beam evaporation requires fast feedback control in order to keep the evaporation rate constant. We can achieve such control with chopped line-of-sight ion gauges, i.e., chopped-ion-gauge evaporation rate monitor (ERM). Note the ERM can become very noisy above 10⁻⁵ Torr due to modulation of the dc ion current of the gas caused by microphonic motion of the gauge elements. Components of this noise in the lock-in band pass become important at higher gas pressures.

Atomic absorption spectroscopy gives us more opportunities to explore a higher oxygen pressure. For further detailed teachings on atomic absorption spectroscopy, readers are referred to a related publication, “Atomic Flux Measurement by Diode-Laser-Based Atomic Absorption Spectroscopy”, J. Vac. Sci. Technol. A17 (1999) 2676, by co-inventors Wang et al., which is hereby incorporated by reference. Briefly, the light from external-cavity tunable-diode lasers is passed into the chamber via optical fibers, coupled to a lens that directs the beam through the evaporants and into the receiving fiber that goes back out of the chamber to the detectors. The amount of absorption is kept constant using a closed-loop feedback circuit, so that the cation flux ratio is maintained constant during deposition.

Atomic oxygen, when desired at high flux, is generated in a microwave-induced discharge, operating at 2.45 GHz. The microwave-input power is 100 to 300 W. Oxygen is introduced through an ˜1″ inner diameter quartz tube, which is enclosed by the cavity, then goes into the vacuum chamber and impinges on the substrates. During the deposition, the pressure at the discharge is 1-2 Torr, while the pressure inside the chamber is 5×10⁻⁵ Torr. Periodically, the quartz tube is treated internally with a concentrated solution of boric acid in order to minimize recombination at the walls.

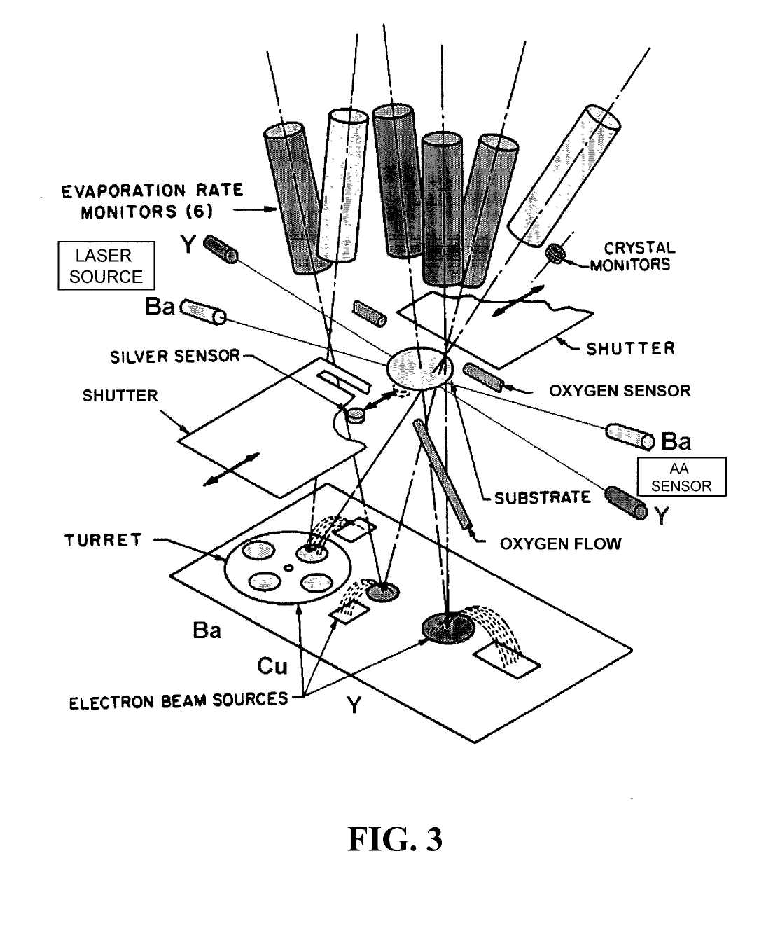

An exemplary system setup for implementing the present invention is illustrated in FIG. 3. The system for in-situ high rate growth of a high quality high temperature superconducting film, such as YBCO, includes a vacuum chamber having a background pressure being maintained close to 3×10⁻⁵ Torr. A substrate, e.g., SrTiO₃, LAO, MgO, sapphire, and IBAD YSZ/Ni, IBAD MgO/Ni, and RABiTS, is positioned in the vacuum chamber where a local pressure is about 2×10⁻⁴ Torr. A liquid flux such as a BaₓCu_{y}O_{z} liquid flux is introduced to cover a surface of the substrate. Activated oxygen is generated in a microwave-induced discharge chamber and introduced through a quartz tube into the vacuum chamber and impinges on the substrate via a Teflon tube. A deposition means supplies atoms, e.g., Y, Ba, and Cu, onto a surface of the liquid flux to grow the superconducting film. The deposition technique is not limited to in-situ e-beam deposition, sputtering, flame spraying, combustion chemical vapor deposition, pulsed laser deposition, and MOCVD, hot cluster (plasma flash) deposition, and cathodic arc deposition. A controller monitors and maintains the liquid flux in a thermodynamic equilibrium with the superconducting film such that the superconducting film grows or is precipitated from the liquid flux at an interface between the liquid flux and the substrate and the film stabilizes on the substrate.

As discussed herein, too much (>10¹⁶ atom/cm²sec) atomic oxygen flux can result in YBCO destruction. Fluxes greater than approximately 10¹⁵ atoms/cm²sec give single phase YBCO, but with a (103) orientation mixed with the desired (001) orientation. In FIG. 2, this corresponds to the right of the BaCuO melting curve. The best YBCO (low resistivity, high critical current density, and strong (001) intensities of XRD reflections) results when no atomic oxygen flux is deliberately introduced. Measurements here have shown that the electron-beam heated metal sources produce atomic oxygen, probably less than 10⁻atoms/cm²sec, when molecular oxygen is present. The presence of the atomic oxygen may be due to the secondary electrons (˜100 eV, where the cross-section for electron impact dissociation of O₂ is largest), or dissociation of the molecule at the hot molten surface of Ba and/or Y, by the electron stimulated dissociation of the metal oxides (DIET, or dissociation induced by electron transition). The best samples are to the left of the BaCuO melting curve in FIG. 2.

Compositions and depth profiles of the films were analyzed by inductively coupled plasma emission spectroscopy (ICP), Auger electron spectroscopy (AES), and secondary ion mass spectroscopy (SIMS). Samples were dipped into a liquid helium dewar for resistivity measurements using four-point method. Crystal structure and phases were characterized by x-ray diffraction (XRD) using Cu Ka radiation. Surface and cross-sectional morphology were investigated by scanning electron microscopy (SEM) and transmission electron microscopy (TEM).

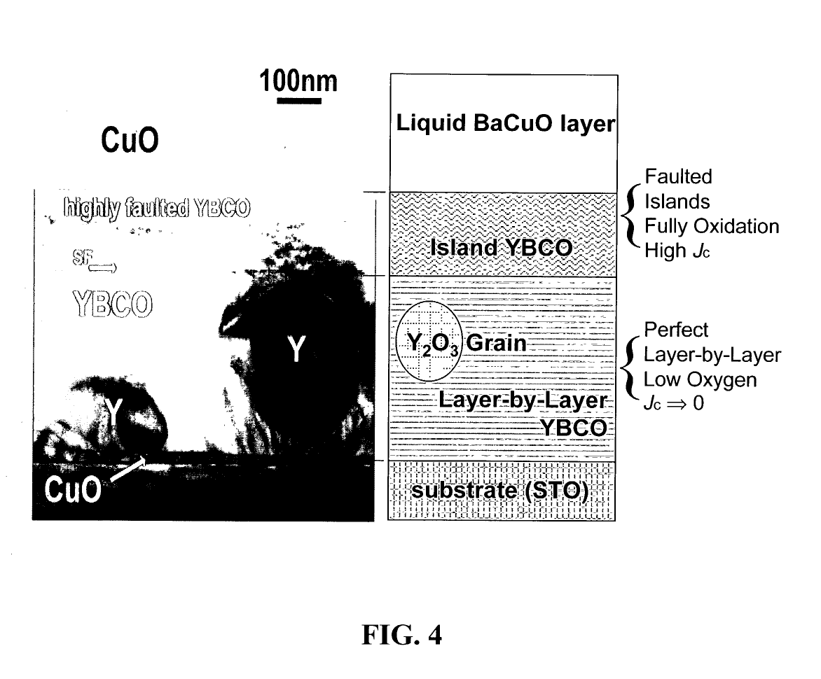

FIG. 4 shows a transmission electron micrograph (TEM) of an in-situ grown YBCO film on SrTiO₃ with molecular oxygen during deposition. As discussed above, low fluxes of atomic oxygen are assumed. As shown in the TEM, the film includes secondary phases such as Y₂O₃ and CuO as well as the YBCO phase, which are confirmed by energy dispersive x-ray analysis for each grain. Y₂O₃ is formed as spherical-like grains and CuO epitaxial grains were occasionally found at the substrate interface, and at the top surface as an amorphous state. Similar microstructures were observed in BaF-post-annealed YBCO films. Y₂O₃ grains appeared to have an epitaxial relationship to the substrate as shown in the TEM, which was also found in XRD patterns. The YBCO phase is composed of two types of grains; defect-less crystals and faulted grains. The defect-less crystal shows a perfect layer of YBCO lattice planes whereas the faulted grains have stacking faults and extra CuO chain layers. It has been considered that faulted grains allow higher critical currents, which require low angle grain boundaries and pinning centers for fluxes. The correlations between the TEM view and the electrical properties (resistivity, critical temperature, and critical current density) were also investigated. A wide range of critical current density has been measured, up to >2 MA/cm² at 77 K and 0 Torr. The value may well be several times higher when the thickness of the pinning YBCO is determined.

As discussed herein, to understand the growth behavior of the YBCO films, it is useful to look into single crystal growth using LPE of YBCO in a liquid flux of BaₓCu_{y}O_{z} such as the method reported by Kawasaki et al. In Kawasaki et al., single crystalline thin YBCO films were grown at 200 mTorr of O₂ using LPD at low rate (˜1 Å/sec) onto a liquid flux of BaCu₂O₂. Specifically, a BaCu₂O₂ film is deposited on a seed YBCO film, which is deposited in advance on SrTiO₃, melted it by heating to 880° C., and after cooling slightly, supplied laser ablated YBCO elements on the liquid surface. A part of the YBCO seed layer dissolves in the liquid phase until a thermodynamical equilibrium state is reached. The Y, Ba, and Cu atoms are deposited onto the liquid and YBCO grows epitaxially at the substrate. This method has the advantage to grow stoichiometric thin films due to thermodynamic equilibrium of the liquid-solid interface, even if there is a slight deviation and/or fluctuation in the composition of the gas phase precursors. The present invention differs from Kawasaki et al. at least in that the inventive techniques disclosed herein do not require the seed layer of YBCO and the separate layer of the BaCuO liquid. Such difference may contribute to the observed large Y₂O₃ spheroids and change from single crystal to faulted grains. Other differences were discussed earlier.

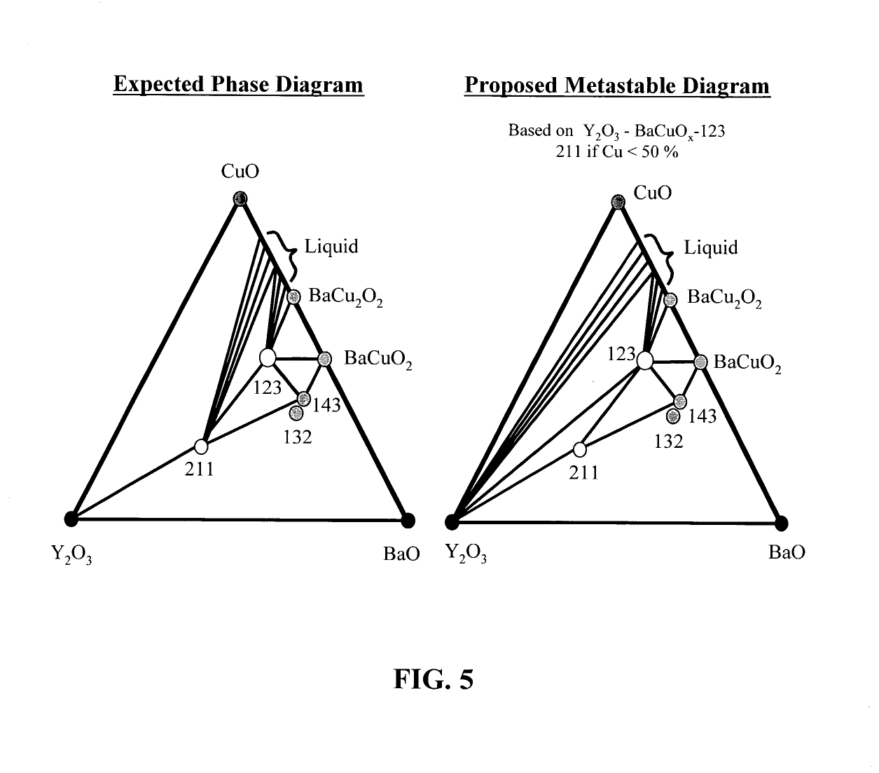

FIG. 5 illustrates phase relationship as expected for the pressure-temperature region based on bulk samples, and the proposed metastable diagram based on finding Y₂O₃ co-existing with YBCO and BaCuO liquid. The Y₂O₃ phase is thermodynamically metastable with formation of BaₓCu_{y}O_{z} phases during growth of YBa₂Cu₃O₇₋ₓ phase. After deposition and cooling, the liquid decomposes into CuO and BaCuO₃.

According to an aspect of the invention, in-situ high rate growth of YBa₂Cu₃O_{7-δ}(YBCO) superconducting films has been carried out using e-beam deposition. SrTiO₃ (STO) and LaAlO₃ (LAO) single crystal substrates were used as well as YSZ on Ni alloy tape prepared by IBAD. To understand both kinetic and thermodynamic stability, a wide range of temperatures, deposition rates, and oxygen fluxes including atomic, molecular oxygen, were investigated. Critical current density (J_{c}) above 1 MA/cm² was achieved on STO substrate samples with growth rates up to 75 Å/sec. J_{c} above 2 MA/cm² were achieved on LAO at rates greater than 100 Å/sec. Samples prepared on IBAD YSZ/Ni tapes exhibit similar resistivity properties and x-ray diffraction patterns.

Since the ERM is limited above 10⁻⁴ Torr pressure, a deposition flux controller was developed for real-time monitoring and fast PID feedback flux controlling using tunable diode, laser-based, atomic absorption (AA) sensor as shown in FIG. 3. A wavelength modulated laser beam shines through the evaporation plume onto a detector. Atomic absorption is then measured by comparing the laser beam that passes through the plume, and the reference beam that splits from the laser source. Since this absorption is proportional to the atomic flux assuming constant velocity in the plume, the vapor flux can be determined. The flux signals are feedback to a PID controller that directs the e-beam power supply to the desired flux level. Unlike the ERM used in the earlier example or a conventional quartz crystal monitor, the AA sensor is installed outside and is independent of the chamber pressure. Each atomic flux can be resolved from the plume by their individual energy level.

Atomic and molecular oxygen are used. The atomic oxygen is generated in a microwave-induced discharge chamber. The oxygen flow is introduced through a quartz tube into the vacuum chamber and impinges on the substrate via a Teflon tube. Atomic oxygen flux near the substrate is measured to be 10¹⁴ to 10¹⁶ atoms/cm²-sec. The background pressure during deposition is maintained close to 3×10⁻⁵ Torr. We estimate the local pressure at the substrate is ˜2×10⁻⁴ Torr when 40 sccm flow rate is used.

After deposition, the chamber is vented to oxygen. The whole cooling cycle after deposition takes about 10 minutes. In general, samples are intentionally Y and Cu rich by ˜5%. Growth rates in this example are 13-100 Å/sec. Substrate temperature during deposition is 800 to 900° C. Thickness of the film range from ˜4000 Å to several microns.

STO, LAO and sapphire crystal substrates are used. Sapphire is used for inductively coupled plasma emission spectroscopy (ICP) analysis. Compositions are found to be the same for the sapphire and the other substrates except for ultra-low oxygen flux case as discussed herein. The IBAD YSZ/Ni tapes are provided by Los Alamos National Laboratory (LANL).

Composition and depth profiles of the samples are analyzed by ICP, Auger electron spectroscopy (AES), SEM, and secondary ion mass spectroscopy (SIMS). Resistivity is measured using four-point method in a liquid helium dewar. Critical current is obtained at liquid nitrogen (77 K ) using Keithley 181 nanovoltmeter and Keithley 228A current source by 1 μV/cm criterion. Crystal structures and phases are characterized by x-ray diffraction (XRD) using Cu K_{α} radiation. Profile fitting of XRD spectra is used to resolve the mixture of phases and possible splittings of each reflection.

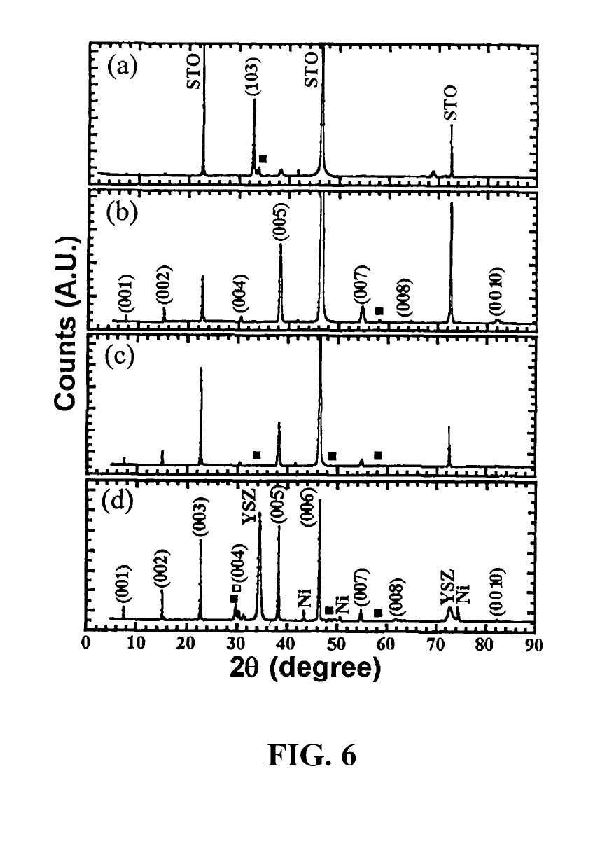

Below ˜830° C., YBCO decomposition is observed when ˜10¹⁶ atom/cm²-sec atomic oxygen flux is used where it decomposes into Y₂O₃ and Ba₂Cu₃O_{5.9}. This observation is exemplified as decomposition line A in FIG. 2. Single phase YBCO with a (103) orientation is obtained when oxygen flux ˜10¹⁵ atoms/cm²-sec is used as shown in FIG. 6(a). FIG. 6 shows selected x-ray diffractograms of in-situ grown YBCO films: (a) 13 Å/sec at 820° C. with atomic oxygen, (b) 50 Å/sec at 880° C. with molecular oxygen, (c) and (d) 100 Å/sec at 895° C. with molecular oxygen. (a), (b), and (c) are on STO substrates, while (d) is on an IBAD YSZ/Ni tape. Strong YBCO (103) is found on (a) while (b) to (d) are highly c-axis epitaxial. Secondary phases such as Y₂O₃, CuO, Ba₂Cu₃O_{5 9} and YBCO-211 are identified in some samples. Y₂O₃ residences in every sample as marked by (▪). BaZrO₃ (□) is identified in IBAD samples that indicates interaction between YBCO and YSZ buffer layer.

The c-axis epitaxial YBCO appears only at a temperature higher than 850° C. when deposited with molecular oxygen. The best result comes from temperature at 885±5° C. J_{c}>1 MA/cm² at 77 K, zero field, has been achieved on 15, 50, 75, and 100 Å/sec deposition rate on STO and LAO samples. As can be seen in FIGS. 6(b) and 6(c), samples prepared at 50 and 100 Å/sec, respectively, are highly c-axis epitaxial. φ-scan of pole's linewidth ˜0.74(2)° for the highest J_{c} samples observed implies it is in-plane aligned as well. Profile fittings show splittings on YBCO (001) reflections that correspond to two types of YBCO with different lattice constants: c=1.680(3) and 11.730(5) Å, average grain sizes: 5000 and 800 Å, and lattice strains: 0.12(2) and 0.35(5)%. Area ratio of these two types of YBCO is roughly 1:3 (former to latter). Judged by lattice constant, their oxygen contents are estimated to be 6.99(1) and 6.82(3). Different types of YBCO are verified by TEM images: faulted YBCO near surface and perfect YBCO at the substrate interface. Referring to FIG. 4 where a TEM image of a 50 Å/sec in-situ grown YBCO film on STO substrate is shown. As discussed before, the sample is deposited at 885° C. with molecular oxygen and atomic oxygen. Secondary phases such as Y₂O₃ and CuO are identified by energy dispersive x-ray analysis. The faulted grains carry high currents that require low angle grain boundaries and pinning centers. Thickness of the faulted YBCO range from roughly one third to equal that of the perfect YBCO. This agrees with the XRD area ratio. Correlation between microstructure of the film and its transportation properties may be further investigated. J_{c} may be much higher when current carrier portion of the YBCO is determined.

The molecular oxygen partial pressure employed in this embodiment is many orders below the well-established decomposition line d₁(O₂) of FIG. 1. The phase stability shown in FIG. 2 is attributed to the presence of atomic oxygen that may be generated by secondary electrons (˜100 eV, which is about the peak in the electron impact cross section) near the e-beam evaporator (dissociated from molecular oxygen), or the hot molten surface of metal oxides on Ba and/or Y sources (electron stimulated dissociation). The atomic oxygen flux was estimated to be ˜10¹⁴ atoms/cm²-sec. The effective oxygen activity is estimated as shown in FIG. 2.

Y₂O₃ particles with 2000-3000 Å diameters have been observed. A tentative understanding of growth morphology is as follows: highly active Y atoms react with atomic oxygen forming Y₂O₃ solid along with a liquid phase of BaₓCu_{y}O_{z} flux. The YBCO phase then grows in the BaₓCu_{y}O_{z} liquid flux, nucleating at the substrate. For related teachings on growth morphology, readers are referred to Kawasaki et al., supra, and “High Growth Rate Deposition Techniques for Coated Conductors: Liquid Phase Epitaxy and Vapor-Liquid-Solid Growth” by Hirabayoshi et al., IEEE Trans. Appl. Supercond. 9 (1999) 1979.

Two batches of IBAD YSZ/Ni tapes are used: with and without CeO₂ cap. BaCeO₃ is always found on the latter that implies interaction between YBCO and CeO₂ buffer layer. The CeO₂ is thought to react with YBCO above 800° C. FIG. 6(d) shows an XRD spectrum from a 100 Å/sec in-situ grown YBCO sample at 895° C. with molecular oxygen on YSZ IBAD tape (has no CeO₂ cap). As can be seen in FIG. 6(d), strong (001) reflections indicate it is highly c-axis epitaxial. BaZrO₃ is identified that suggests the YSZ buffer layer also reacts at high temperature.

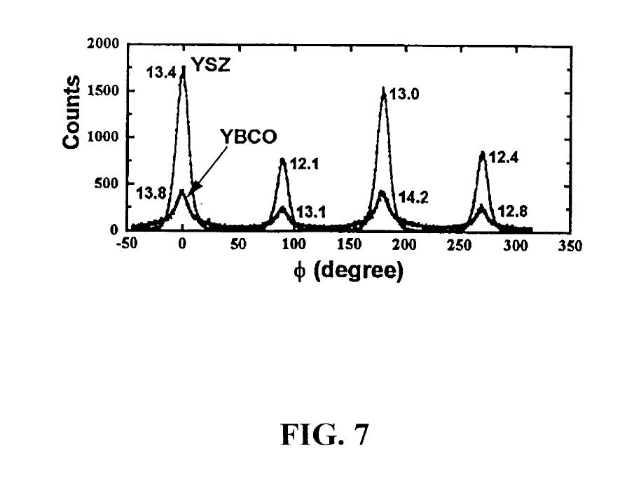

Superconducting temperatures of these YBCO tapes exhibit similar features as the YBCO/STO samples at the same run. However, J_{c} is only about 5 kA/cm² or lower. X-ray φ-scan on eight selected tapes that extend over 40-100 Å/sec growth rate shows an average FWHM˜13° of each pole, and non-zero background between poles, that indicate poor in-plane alignment. The results are weak-links between grain boundaries that depress the J_{c} significantly. FIG. 7 shows a φ-scan from an 85 Å/sec in-situ grown tape sample that was deposited at 895° C. with molecular oxygen. The scan is over YSZ (111) and YBCO (103) peak, respectively. Linewidth of each pole is as indicated. Non-zero background between poles for YBCO suggests a fraction of poorly aligned grains. Since both of the YSZ and the CeO₂ buffer layers on IBAD YSZ/Ni tapes react with YBCO, a temperature stable buffer layer would be necessary for this high temperature process. The alternative is to reduce the process temperature, which is being attempted.

In conclusion, YBCO superconducting films on LAO substrates at high rates have been shown to grow at 885° C. with high atomic oxygen fluxes. Evidence of a growth in a liquid flux is found by the morphology of platelet grains in a laminated structure in the case of high atomic oxygen fluxes. This structure is not observed in the YBCO films grown in molecular oxygen with small amount of atomic oxygen. The YBCO together with the Y₂O₃ is evidence of growth in a liquid flux of BaₓCu_{y}O_{z}. This result can be explained from the phase diagram as shown in FIG. 5 and is described by new decomposition lines of YBCO phase with atomic and molecular oxygen as shown in FIG. 2. Further, in-situ YBCO superconducting films have been shown to grow on STO, LAO, and IBAD YSZ/Ni substrates. Growth rates of 13-100 Å/sec, 800-900° C. substrate temperature with fluxes of atomic and molecular oxygen were demonstrated. Thermodynamic phase stability is attributed to the presence of atomic oxygen during deposition. Decomposition limits of YBCO for atomic oxygen agree with those estimated in FIG. 2. Critical current density˜1 MA/cm² has been achieved on STO samples up to 75 Å/sec growth rate and >2 MA/cm² at 100 Å/sec on LAO samples. Microstructure of the YBCO together with the presence of Y₂O₃ suggest the growth is in a BaₓCu_{y}O_{z} liquid flux.

It will be clear to one skilled in the art that the above embodiments may be altered in many ways without departing from the scope of the invention. For example, the high mobility that the liquid flux may allow methods that supply the vapor of atoms to be generalized to other methods that meet the requirement of pressure and activated oxygen, or other elements in other cases, e.g., nitrogen to grow nitrides. These include PLD, sputtering, flame spraying, combustion chemical vapor deposition, MOCVD, hot cluster (plasma flash) deposition, and cathodic arc deposition, and the like. Other materials include the rare earth substitutions for Y (La, Nd, Sm, Eu, Gd, Tb, Dy, Ho, Er, Tm, Yb, Lu), and any systems where the compound of interest is in equilibrium with a liquid phase. Accordingly, the scope of the invention should be determined by the following claims and their legal equivalents.

We claim:

1. A method for growing a solid state film from a liquid, said method comprising the steps of:
a) providing a substrate;
b) covering said substrate with said liquid;
c) establishing and maintaining a growing atmosphere around said substrate, wherein activated oxygen or nitrogen is introduced and controlled in said growing atmosphere; and
d) supplying atoms for growing said film onto a surface of said liquid; and
e) maintaining said liquid in a thermodynamic equilibrium with said film such that said film grows or is precipitated from said liquid and said film nucleates at and stabilizes on said substrate.

2. The method of claim 1, wherein said step of establishing and maintaining said growing atmosphere further comprising a step of reducing atmosphere pressure to less than 10⁻⁴ Torr.

3. The method of claim 1, wherein said atoms are Y, Ba, and Cu atoms and said liquid flux is a BaₓCu_{y}O_{z} liquid flux.

4. A method for in-situ high rate growth of a high quality high temperature superconducting film from a liquid flux at reduced pressure, said method comprising the steps of:
a) providing a substrate;
b) covering said substrate with said liquid flux;
c) establishing and maintaining a growing atmosphere substantially below atmospheric pressure around said substrate, wherein activated oxygen and molecular oxygen are introduced and controlled in said growing atmosphere; and
d) continuously supplying atoms for growing said film onto a surface of said liquid flux; and
e) maintaining said liquid flux in a thermodynamic equilibrium with said film such that said film grows or is precipitated from said liquid flux at an interface between said liquid flux and said substrate and said film stabilizes on said substrate.

5. The method of claim 4, wherein said substrate is selected from the group consisting of SrTiO₃, LAO, sapphire, IBAD YSZ/Ni, IBAD-MgO/Ni, and RABiTS substrates.

6. The method of claim 4, wherein said atoms are Y, Ba, and Cu atoms and said liquid flux is a BaₓCu_{y}O_{z} liquid flux.

7. The method of claim 4, wherein said step of establishing and maintaining said growing atmosphere further comprising a step of reducing atmosphere pressure to less than 5×10⁻⁵ Torr.

8. The method of claim 4, wherein a partial pressure of said activated oxygen is less than 10⁻⁴ Torr.

9. The method of claim 4, wherein said film comprises a superconducting oxide.

10. The method of claim 9, wherein said superconducting oxide is yttrium-barium-copper-oxide (YBCO).

11. The method of claim 4, wherein said step of supplying atoms comprises a step of vapor depositing said atoms on said surface.

12. The method of claim 4, wherein said step of supplying atoms comprises a technique selected from the group consisting of in-situ e-beam deposition, sputtering, flame spraying, combustion chemical vapor deposition, pulsed laser deposition, MOCVD, hot cluster (plasma flash) deposition, and cathodic arc deposition.

13. A system for in-situ high rate growth of a high quality high temperature superconducting film, said system comprising:
a vacuum chamber having a background pressure being maintained close to 3×10⁻⁵ Torr;
a substrate positioned in said vacuum chamber and having a local pressure of about 2×10⁻⁴ Torr;
a liquid flux covering a surface of said substrate;
activated oxygen generated in a microwave-induced discharge chamber and introduced through a quartz tube into said vacuum chamber and impinges on said substrate via a Teflon tube;
a deposition means for supplying atoms for growing said film onto a surface of said liquid flux; and
a controlling means for maintaining said liquid flux in a thermodynamic equilibrium with said film such that said film grows or is precipitated from said liquid flux at an interface between said liquid flux and said substrate and said film stabilizes on said substrate.

14. The system of claim 13, wherein said deposition means further comprising:
an in-situ e-beam; and
a deposition controller means for monitoring and controlling deposition rates.

15. The system of claim 14, wherein said deposition controller comprises a tunable diode laser based atomic absorption sensor capable of real-time monitoring and fast PID feedback flux controlling.

16. The system of claim 13, wherein said substrate is selected from the group consisting of SrTiO₃, LAO, MgO, sapphire, and IBAD YSZ/Ni, IBAD MgO/Ni, and RABiTS substrates.

17. The system of claim 13, wherein said atoms are Y, Ba, and Cu atoms and said liquid flux is a BaₓCu_{y}O_{z} liquid flux.

18. The system of claim 13, wherein said film comprises a superconducting oxide.

19. The system of claim 18, wherein said superconducting oxide is yttrium-barium-copper-oxide (YBCO).

20. The system of claim 13, wherein said deposition means is selected from the group consisting of sputtering, flame spraying, combustion chemical vapor deposition, pulsed laser deposition, and MOCVD, hot cluster (plasma flash) deposition, and cathodic arc deposition.
